(19) United States
(12) Patent Application Publication
(10) Pub. No.: US 2018/0076318 A1
(43) Pub. Date: Mar. 15, 2018

(54) SEMICONDUCTOR DEVICE AND METHOD OF MANUFACTURING THE SAME

(71) Applicant: Renesas Electronics Corporation, Tokyo (JP)

(72) Inventor: Yasuhiro NISHIMURA, Tokyo (JP)

(21) Appl. No.: 15/652,402

(22) Filed: Jul. 18, 2017

(30) Foreign Application Priority Data
Sep. 14, 2016 (JP) 2016-179296

(51) Int. Cl. H01L 29/78; H01L 29/10; H01L 29/06; H01L 29/66

(52) U.S. Cl. CPC H01L 29/7815; H01L 29/7813; H01L 29/66734; H01L 29/0696; H01L 29/1095

(57) ABSTRACT

According to an embodiment, semiconductor device 1 includes: a drift layer 12 of a first conductivity type; a base layer 13 of a second conductivity type; a source layer 30 of the first conductivity type; a gate trench 21 penetrating the source layer 30 and the base layer 13, and reaching the drift layer 12; a gate electrode 20 and a gate insulating film disposed inside the gate trench 21; an interlayer insulating film 42; a contact hole 43 penetrating the interlayer insulating film 42, the source layer 30, and the base layer 13, and reaching the drift layer 12; a snubber conductive layer 50 disposed in a lower part of the contact hole 43; a snubber sidewall insulating film 55 disposed between a side surface of the snubber conductive layer 50 and the drift layer 12; and a contact 41 disposed above the snubber conductive layer 50 in the contact hole 43 and connected to the source layer 30.

### CROSS-REFERENCE TO RELATED APPLICATIONS

This application is based upon and claims the benefit of priority from Japanese patent application No. 2016-179296, filed on Sep. 14, 2016, the disclosure of which is incorporated herein in its entirety by reference.

### BACKGROUND

The present disclosure relates to a semiconductor device and a method of manufacturing the same, and to, for example, a semiconductor device including a power MOSFET and a method of manufacturing the same.

A power MOSFET (Metal-Oxide-Semiconductor Field-Effect Transistor) is a MOSFET designed to handle a large amount of power and is used as a switching element.

In regard to the power MOSFET, a trench gate MOSFET has been developed. The trench gate MOSFET includes gate trenches formed on a surface thereof, and gate electrodes buried inside the gate trenches for a low on resistance and high voltage resistance.

Japanese Unexamined Patent Application Publication No. 2014-187237 describes that, in a trench gate power MOSFET, a buried conductive layer and an insulating film covering a side surface of the buried conductive layer are formed at lower parts of gate electrodes. Japanese Unexamined Patent Application Publication No. 2014-187237 further describes that, by using the buried conductive layer as a source potential, electric fields are not concentrated near the gate electrode, and thus the low on resistance and high voltage resistance can be achieved.

When a switching element such as a power MOSFET used in a motor drive inverter is turned on or off, ringing of voltage and current occurs due to parasitic LC included in the elements and the semiconductor substrate including the elements.

As shown in FIG. 11, when the power MOSFET is off, ringing occurs in a drain-source voltage Vds. The generated ringing propagates to a power supply line and causes Electro-Magnetic Interference (EMI) to be generated, which adversely affects electronic devices disposed near the power MOSFET.

Thus, as shown in FIG. 12, in a semiconductor device 100 according to related art, a drain layer 111, a drift layer 112, a base layer 113, and a source layer 130 are disposed in a semiconductor substrate 110 that is between a drain electrode 145 and a source electrode 144. Further, gate electrodes 120 and gate insulating films 125 are formed inside gate trenches 121 that penetrate the source layer 130 and the base layer 113 and reach the drift layer 112. In order to reduce the EMI, a buried conductive layer 190 covered with an insulating film 195 is formed just beneath each of the gate electrodes 120, and the buried conductive layer 190 is connected to the source electrode 144 at a circumferential part of the semiconductor device 100. Note that a contact 141 is formed in a contact hole 143 penetrating an interlayer insulating film 142.

As shown in FIG. 13, in the semiconductor device 100 of the related art, the buried conductive layers 190 and the insulating films 195 constitute a snubber circuit. With such a configuration, it is possible to have a resistance R formed by the buried conductive layers 190 and a capacitance Cds formed between the buried conductive layers 190 and the drain layer 111. In this way, noise caused by EMI is reduced in the semiconductor device 100 of the related art.

However, the buried conductive layers 190 are uniquely designed with a predetermined size and shape, because the buried conductive layers 190 is formed just beneath the gate electrodes. It is therefore difficult to change the thickness of the buried conductive layers 190 in the Z axis direction and the length in the Y axis direction. Note that the XYZ coordinate axis system is specified as shown in FIG. 12.

On the other hand, as the noise caused by EMI is not uniquely determined, in order to appropriately reduce such noise, it is necessary to optimize the thickness and the length of the buried conductive layers 190.

An embodiment has been made to solve such a problem, and an object of the present disclosure is to provide a semiconductor device capable of optimizing resistance and capacitance of a snubber circuit and capable of reducing noise caused by EMI and a method of manufacturing the semiconductor device.

Other problems of the related art and new features of the present disclosure will become apparent from the following descriptions of the specification and attached drawings.

In an example aspect of the present disclosure, a semiconductor device includes: a drift layer of a first conductivity type; a base layer of a second conductivity type disposed on the drift layer; a source layer of the first conductivity type disposed on the base layer and having a resistance lower than that of the drift layer; a gate trench extended in one direction in an upper surface of the source layer, penetrating the source layer and the base layer, and reaching the drift layer; a gate electrode disposed inside the gate trench; a gate insulating film disposed between the gate electrode and the source layer, between the gate electrode and the base layer, and between the gate electrode and the drift layer; an interlayer insulating film disposed on the source layer; a contact hole extended in the one direction in an upper surface of the interlayer insulating film, penetrating the interlayer insulating film, the source layer, and the base layer, and reaching the drift layer; a snubber conductive layer disposed in a lower part of the contact hole and extended in the one direction; a snubber sidewall insulating film disposed between a side surface of the snubber conductive layer and the base layer and at least between a side surface of the snubber conductive layer and the drift layer; and a contact disposed above the snubber conductive layer in the contact hole and connected to the source layer.

According to the above example aspect, it is possible to provide a semiconductor device capable of optimizing resistance and capacitance of a snubber circuit and capable of reducing noise caused by EMI and a method of manufacturing the semiconductor device.

### BRIEF DESCRIPTION OF THE DRAWINGS

The above and other aspects, advantages and features will be more apparent from the following description of certain embodiments taken in conjunction with the accompanying drawings, in which:

FIG. 1 is a top view illustrating a semiconductor device according to an embodiment;

FIG. 2 is a cross-sectional view illustrating the semiconductor device according to the embodiment and showing a cross section taken along the line A-A′ of FIG. 1;

FIG. 3 is a cross-sectional view illustrating the semiconductor device according to the embodiment and showing a cross section taken along the line B-B′ of FIG. 1;

FIG. 4A is a cross-sectional view illustrating a method of manufacturing the semiconductor device according to the embodiment and illustrating a process for forming a mask in order to form gate trenches;

FIG. 4B is a cross-sectional view illustrating the method of manufacturing the semiconductor device according to the embodiment and illustrating a process for mask lithography;

FIG. 4C is a cross-sectional view illustrating the method of manufacturing the semiconductor device according to the embodiment and illustrating a process for mask patterning;

FIG. 5A is a cross-sectional view illustrating the method of manufacturing the semiconductor device according to the embodiment and illustrating an etching process in order to form the gate trenches;

FIG. 5B is a cross-sectional view illustrating the method of manufacturing the semiconductor device according to the embodiment and illustrating a process of edge-rounding oxidation of the gate trenches;

FIG. 5C is a cross-sectional view illustrating the method of manufacturing the semiconductor device according to the embodiment and illustrating a deposition process of polysilicon in order to form gate electrodes;

FIG. 6A is a cross-sectional view illustrating the method of manufacturing the semiconductor device according to the embodiment and illustrating a process for plasma-etching the polysilicon in order to form the gate electrodes;

FIG. 6B is a cross-sectional view illustrating the method of manufacturing the semiconductor device according to the embodiment and showing a process for impurity implantation in order to form a base layer;

FIG. 6C is a cross-sectional view illustrating the method of manufacturing the semiconductor device according to the embodiment and showing a process for impurity implantation in order to form a source layer;

FIG. 7A is a cross-sectional view illustrating the method of manufacturing the semiconductor device according to the embodiment and showing a process for forming an interlayer insulating film;

FIG. 7B is a cross-sectional view illustrating the method of manufacturing the semiconductor device according to the embodiment and illustrating a process for plasma etching in order to form the contact hole and a process for impurity implantation in order to form a connection layer;

FIG. 7C is a cross-sectional view illustrating the method of manufacturing the semiconductor device according to the embodiment and illustrating a process for field plate oxidation;

FIG. 8A is a cross-sectional view illustrating the method of manufacturing the semiconductor device according to the embodiment and illustrating a process for ion-etching an oxide film on a bottom surface of the contact hole;

FIG. 8B is a cross-sectional view illustrating the method of manufacturing the semiconductor device according to the embodiment and illustrating a deposition process of polysilicon in order to form a snubber conductive layer;

FIG. 8C is a cross-sectional view illustrating the method of manufacturing the semiconductor device according to the embodiment and illustrating a process for etching back the polysilicon in order to form the snubber conductive layer;

FIG. 9A is a cross-sectional view illustrating the method of manufacturing the semiconductor device according to the embodiment and illustrating a process for forming an oxide film in order to form a buried insulating film;

FIG. 9B is a cross-sectional view illustrating the method of manufacturing the semiconductor device according to the embodiment and illustrating a process for etching the oxide film in order to form a contact;

FIG. 10 is a top view illustrating the semiconductor device according to the embodiment;

FIG. 11 is a graph illustrating a switching waveform of a MOFFET according to related art, where the horizontal axis represents time and the vertical axis represents a voltage;

FIG. 12 is a cross-sectional view illustrating the configuration of the MOSFET according to the related art; and

FIG. 13 is a circuit diagram illustrating a configuration and an equivalent circuit of the MOSFET according to the related art.

### DETAILED DESCRIPTION

To clarify the description, some parts thereof and some of the drawings have been omitted or simplified as appropriate. In the drawings, the same elements are denoted by the same reference signs, and repeated descriptions are omitted as necessary.

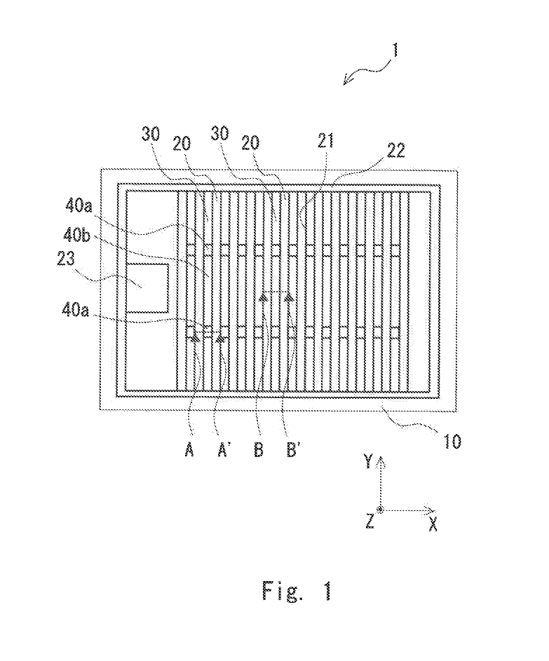

A configuration of a semiconductor device according to an embodiment will be described. FIG. 1 is a top view illustrating the semiconductor device according to the embodiment. As shown in FIG. 1, a semiconductor device 1 includes a semiconductor substrate 10. On the semiconductor substrate 10, gate electrodes 20, a circumferential gate line 22, a gate pad 23, and a source layer 30 are disposed.

The gate electrodes 20 are buried in gate trenches 21 formed in an upper surface of the semiconductor substrate 10. The plurality of gate trenches 21 are formed in the upper surface of the semiconductor substrate 10. Each gate trench 21 is extended in one direction in a plane parallel to the upper surface of the semiconductor substrate 10. Therefore, the plurality of gate electrodes 20 are formed, and each gate electrode 20 is extended in one direction. The gate electrode includes, for example, a polysilicon layer. The gate trenches 21 are disposed in parallel to each other, and thus the gate electrodes 20 are disposed in parallel to each other. The regions between the gate electrodes are referred to as cells.

The XYZ coordinate system is used to describe the semiconductor device 1. The direction orthogonal to the upper surface of the semiconductor substrate 10 is defined as the Z-axis direction. The +Z axis direction is the upward direction, and the −Z axis direction is the downward direction. One direction in a plane parallel to the upper surface of the semiconductor substrate 10, for example, a direction in which the gate electrodes 20 are extended is defined as a Y axis direction. The direction orthogonal to the one direction, for example, the direction in which the gate electrodes 20 are arranged is defined as an X axis direction.

The circumferential gate line 22 is formed on a circumference of the gate electrodes 20 so as to surround the gate electrodes 20. The circumferential gate line 22 is connected to, for example, both ends of the gate electrodes 20 in the +Y axis direction and the −Y axis direction. The circumferential gate line 22 includes, for example, a polysilicon layer. The circumferential gate line 22 is, for example, formed integrally with the gate electrodes 20. Like the gate electrodes 20, the circumferential gate line 22 is buried in a trench formed in the upper surface of the semiconductor substrate 10.

The gate pad 23 is disposed on the semiconductor substrate 10. The gate pad 23 is connected to a part of the circumferential gate line 22. The gate pad 23 is a terminal for connecting the gate electrodes 20 to the outside. The gate pad 23 includes, for example, a polysilicon layer. The gate pad 23 is buried in a recess formed in the upper surface of the semiconductor substrate 10.

A source electrode is formed in a region surrounded by the circumferential gate line 22 on the semiconductor substrate 10. In FIG. 1, the source electrode is not shown for the sake of simplicity. Further, in FIG. 1, an interlayer insulating film and contacts provided on the semiconductor substrate 10 are also not shown. On the upper surface of the semiconductor substrate 10, a source layer 30 is formed in regions positioned between the respective gate electrodes 20. The source layer 30 is connected to the source electrode via the contacts.

The semiconductor device 1 includes snubber conductor contacting regions 40a and snubber conductor non contacting regions 40b. The snubber conductor contacting regions 40a are regions where contacts and snubber conductive layers come into contact with each other, which will be described later. The snubber conductor noncontacting regions 40b are regions where the buried insulating films are disposed between the contacts and the snubber conductive layers. The snubber conductive layer noncontacting regions 40b are extended in the Y axis direction. The snubber conductive layer contacting regions 40a are disposed at the end parts or both ends of the snubber conductive layer noncontacting regions 40b.

The line A-A′ shown in FIG. 1 indicates a cross section of the snubber conductor contacting region 40a, and the line B-B′ shown in FIG. 1 indicates a cross section of the snubber conductor noncontacting region 40b.

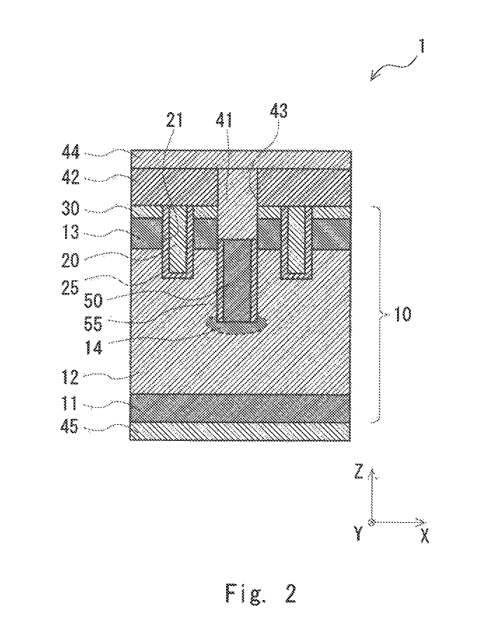

FIG. 2 is a cross-sectional view illustrating the semiconductor device 1 according to the embodiment and illustrating the cross section taken along the line A-A′ of FIG. 1. As shown in FIG. 2, the semiconductor device 1 includes, in the snubber conductor contacting regions 40a, a drain layer 11, a drift layer 12, a base layer 13, the source layer 30, the gate electrodes 20, gate insulating films 25, a contact 41, an interlayer insulating film 42, a snubber conductive layer 50, a snubber sidewall insulating film 55, a connection layer 14, a source electrode 44, and a drain electrode 45. The semiconductor substrate 10 in FIG. 1 includes a part extending from a lower surface of the drain layer 11 to an upper surface of the source layer 30.

The drain layer 11 is, for example, an n⁺ type semiconductor layer doped with a high concentration of an n-type impurity. The drain layer 11 is, for example, a bulk silicon substrate. For the sake of convenience, an n-type may be referred to as a first conductivity type, and a p-type may be referred to as a second conductivity type. Conversely, an n-type may be referred to as a second conductivity type, and a p-type may be referred to as a first conductivity type.

The drift layer 12 is disposed on the drain layer 11. Therefore, the drain layer 11 is in contact with a lower surface of the drift layer. The drift layer 12 is formed, for example, on a silicon layer epitaxially grown on the drain layer 11. The drift layer 12 is an n-type semiconductor layer doped with a low concentration of an n-type impurity. The resistance of the drift layer 12 is greater than that of the drain layer 11.

The base layer 13 is disposed on the drift layer 12. The base layer 13 is a p-type semiconductor layer doped with a p-type impurity such as boron (B).

The source layer 30 is disposed on the base layer 13. Accordingly, the base layer 13 is positioned between the source layer 30 and the drift layer 12. The source layer 30 is, for example, an n⁺ type semiconductor layer doped with a high concentration of an n-type impurity such as arsenic (As). The resistance of the source layer 30 is lower than that of the drift layer 12. The base layer 13 and the source layer 30 are formed on a silicon layer epitaxially grown on the drain layer 11. Therefore, a part of the silicon layer epitaxially grown on the drain layer 11 which will not become the base layer 13 and the source layer 30 is the drift layer 12.

The gate trenches 21 are formed in the semiconductor substrate 10. Thus, the gate trenches 21 are formed in the epitaxially grown silicon layer. The gate trenches 21 are extended in one direction in a plane parallel to the upper surface of the source layer 30. The gate trenches 21 penetrate the source layer 30 and the base layer 13. Further, the gate trenches 21 reach the drift layer 12. Lower ends of the gate trenches 21 are positioned in the drift layer 12.

The gate electrodes 20 are disposed inside the respective gate trenches 21. For example, the gate electrodes 20 include polysilicon and are buried inside the gate trenches 21, respectively. Thus, the gate electrodes 20 penetrate the base layer 13. That is, an upper end of the gate electrode 20 is positioned above an upper end of the base layer 13, and a lower end of the gate electrode 20 is positioned below a lower end of the base layer.

The gate insulating film 25 is formed on an inner surface of the gate trench 21. Therefore, the gate insulating film 25 is formed between the gate electrode 20 and the drift layer 12, between the gate electrode 20 and the base layer 13, and between the gate electrode 20 and the source layer 30. The gate insulating film 25 includes, for example, a silicon oxide film.

The interlayer insulating film 42 is disposed on the semiconductor substrate 10, for example, on the source layer 30. The interlayer insulating film 42 covers the source layer 30, the gate electrodes 20, and the gate insulating film 25 from above the semiconductor substrate 10. The interlayer insulating film 42 includes, for example, a silicon oxide film.

A contact hole 43 is formed in the interlayer insulating film 42. The contact hole 43 is extended in one direction, for example, in a direction in which the gate electrodes 20 are extended, in an upper surface of the interlayer insulating film 42. The contact hole 43 penetrates the interlayer insulating film 42, the source layer 30, and the base layer 13. The contact hole 43 reaches the drift layer 12. A lower end of the contact hole 43 is positioned below the lower ends of the gate trenches 21. The contact hole 43 is disposed between the two gate trenches 21.

The snubber conductive layer 50 is disposed in a lower part of the contact hole 43. For example, the snubber conductive layer 50 is formed by polysilicon and is buried at the lower part of the contact hole 43. An upper end of the snubber conductive layer 50 is positioned, for example, in the base layer 13. That is, the upper end of the snubber conductive layer 50 is positioned above a lower end of the base layer 13, and is positioned below an upper end of the base layer 13.

A lower end of the snubber conductive layer 50 is positioned at a bottom surface of the contact hole 43. The lower end of the snubber conductive layer 50 is positioned below the lower end of the base layer 13 and is positioned above the lower end of the drift layer 12. Further, the lower end of the snubber conductive layer 50 is positioned below the lower end of the gate electrode 20.

The snubber conductive layer 50 is extended in the direction in which the gate electrodes 20 are extended, for example, the Y axis direction. The snubber conductive layer 50 is connected to the source electrode 44 at the circumferential part of the semiconductor device.

A snubber sidewall insulating film 55 is disposed on an inner surface of the contact hole 43. The snubber sidewall insulating film 55 is disposed between a side surface of the snubber conductive layer 50 and the drift layer 12. The snubber sidewall insulating film 55 may also be disposed between the side surface of the snubber conductive layer 50 and the base layer 13. The snubber sidewall insulating film 55 is not formed on the bottom surface of the contact hole 43. That is, a lower surface of the snubber conductive layer 50 is not covered with the insulating film. The snubber sidewall insulating film 55 includes, for example, a silicon oxide film.

The connection layer 14 includes the bottom surface of the contact hole 43 and is disposed near the bottom surface of the contact hole 43. That is, the connection layer 14 is disposed in the semiconductor substrate 10 constituting the bottom surface of the contact hole 43. Lower and side parts of the connection layer 14 are in contact with the drift layer 12. The connection layer 14 is formed so as to be extended in a direction in which the gate electrodes 20 are extended, for example, in the Y direction. The connection layer 14 is a P-type semiconductor layer doped with a P-type impurity such as boron (B). The connection layer 14 is in contact with the snubber conductive layer 50. For example, the connection layer 14 is in contact with the lower end of the snubber conductive layer 50.

A lower end of the connection layer 14 is positioned below a lower end of the snubber sidewall insulating film 55. When viewed from above, the length of the connection layer 14 in the X direction is greater than the length of the snubber conductive layer 50 in the X axis direction.

The contact 41 is disposed in an upper part of the contact hole 43. The contact 41 is disposed above the snubber conductive layer 50 in the contact hole 43. The contact 41 is connected to the source layer 30. In the snubber conductor contacting regions 40a, a lower end of the contact 41 is electrically connected to the snubber conductive layer 50. For example, the lower end of the contact 41 is in contact with the snubber conductive layer 50. When viewed from above, the length of the contact 41 in the X axis direction is greater than the length of the snubber conductive layer 50 in the X axis direction. For example, a material of the contact 41 contains tungsten. Note that the contact 41 may be formed of the same material as that of the source electrode 44.

The source electrode 44 is disposed on the interlayer insulating film 42. The source electrode 44 is connected to the contact 41. A barrier metal film may be formed between the source electrode 44 and the interlayer insulating film 42 and between the interlayer insulating film 42 and the contact 41. A barrier metal film may be formed on the bottom surface of the contact 41. In this case, the contact 41 includes the barrier metal film and is electrically connected to the snubber conductive layer 50.

The drain electrode 45 is disposed to cover a lower surface of the drain layer 11. The drain electrode 45 is connected to, for example, the lower surface of the drain layer 11. The drain electrode 45 and the source electrode 44 include, for example, aluminum. A voltage is applied between the source electrode 44 and the drain electrode.

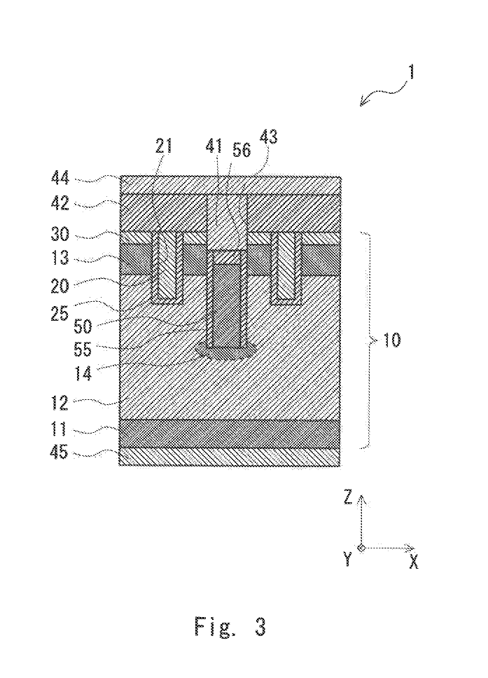

Next, a configuration of the snubber conductor noncontacting regions 40b of the semiconductor device 1 will be described. FIG. 3 is a cross-sectional view illustrating the semiconductor device 1 according to the embodiment and illustrating a cross section taken along the line B-B′ of FIG. 1. As shown in FIG. 3, the snubber conductor noncontacting region 40b of the semiconductor device 1 has the same configuration as that of the snubber conductor contacting regions 40a except for an internal configuration of the contact hole 43. Thus the description of the same configuration will be omitted.

As shown in FIG. 3, a buried insulating film 56 is disposed inside the contact hole 43. The buried insulating film 56 is disposed between the contact 41 and the snubber conductive layer 50. An upper end of the buried insulating film 56 is positioned above the lower end of the base layer 13 and is positioned below the upper end of the base layer 13. A lower end of the buried insulating film 56 is positioned above the lower end of the base layer 13 and is positioned below the upper end of the base layer 13. The buried insulating film 56 is extended in a direction in which the snubber conductive layer 50 is extended. The buried insulating film 56 includes, for example, a silicon oxide film. An upper end of the snubber sidewall insulating film 55 may be extended to the upper end of the buried insulating film 56.

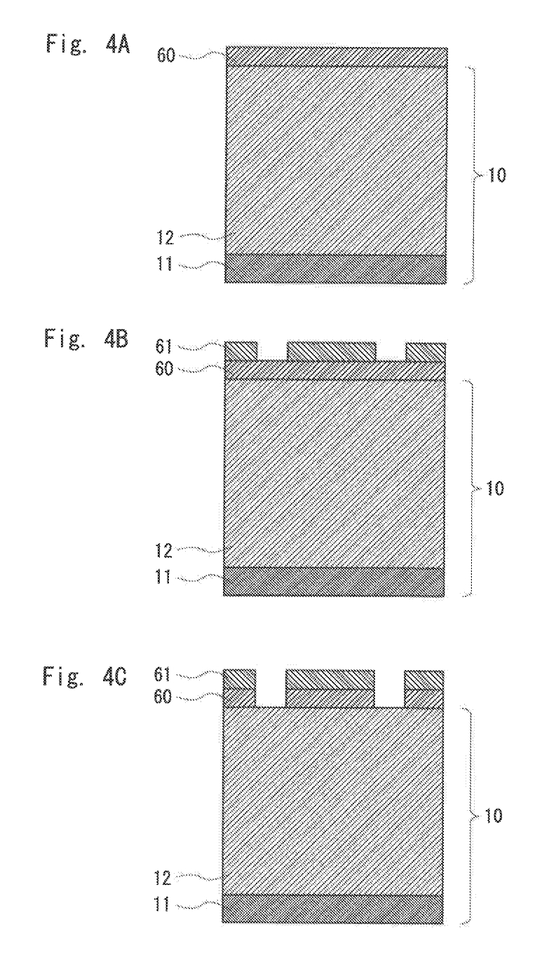

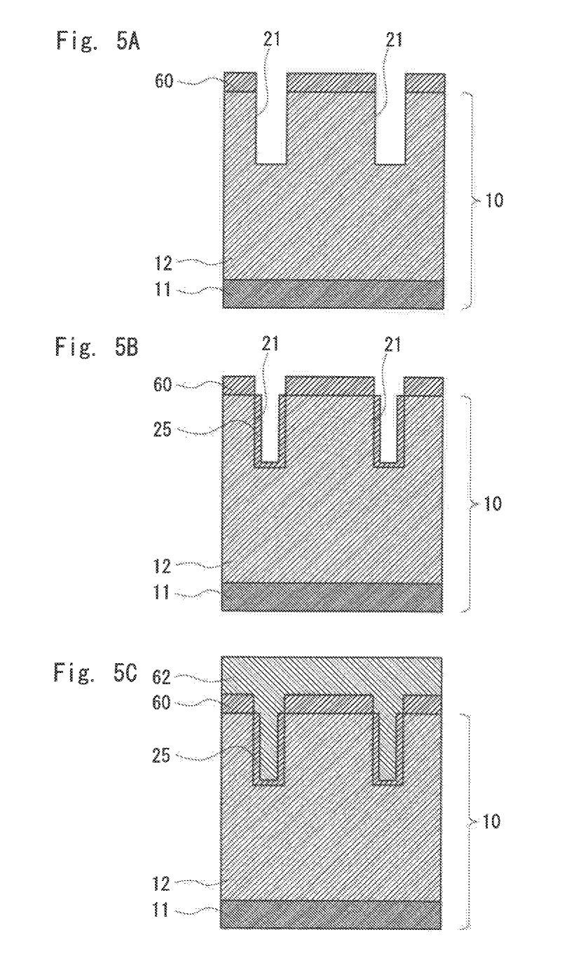

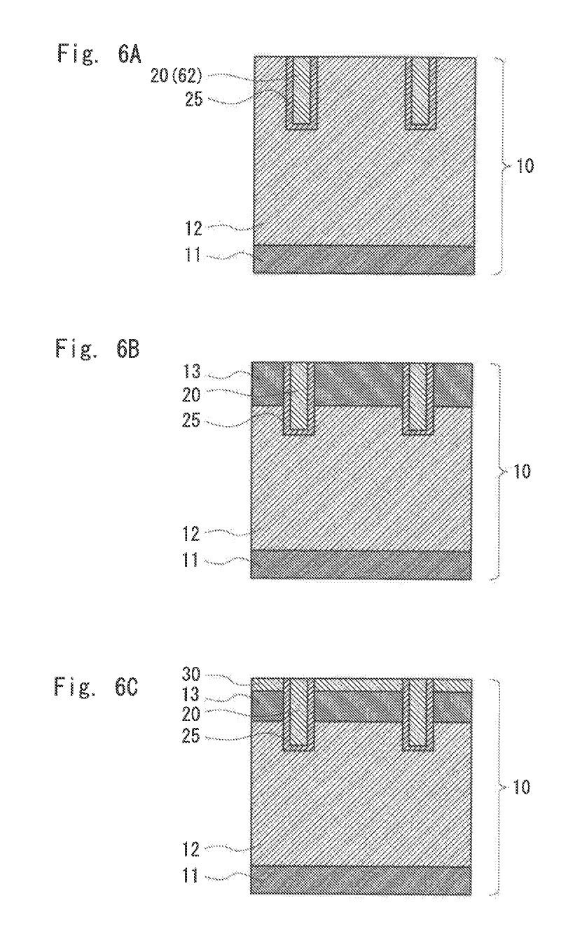

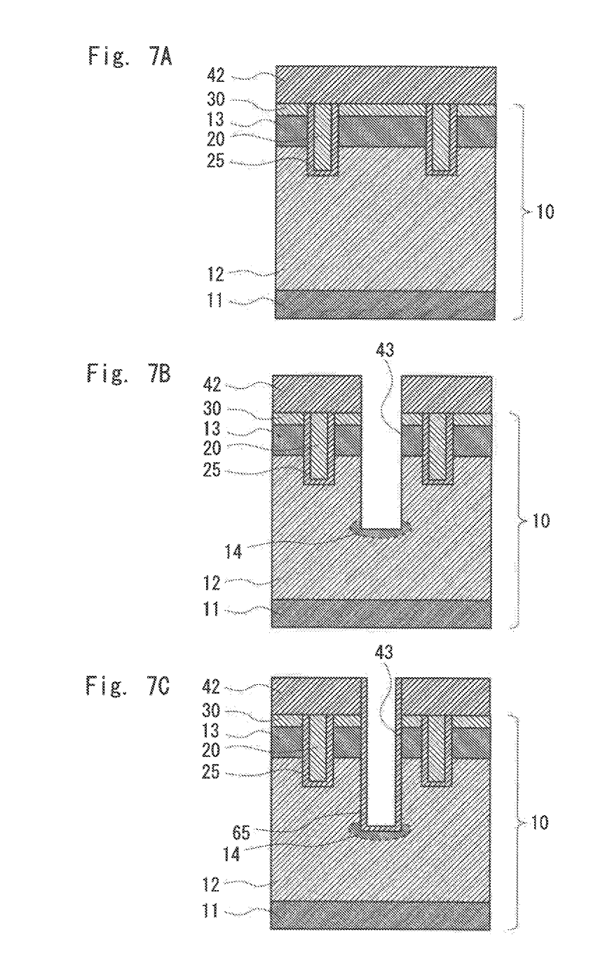

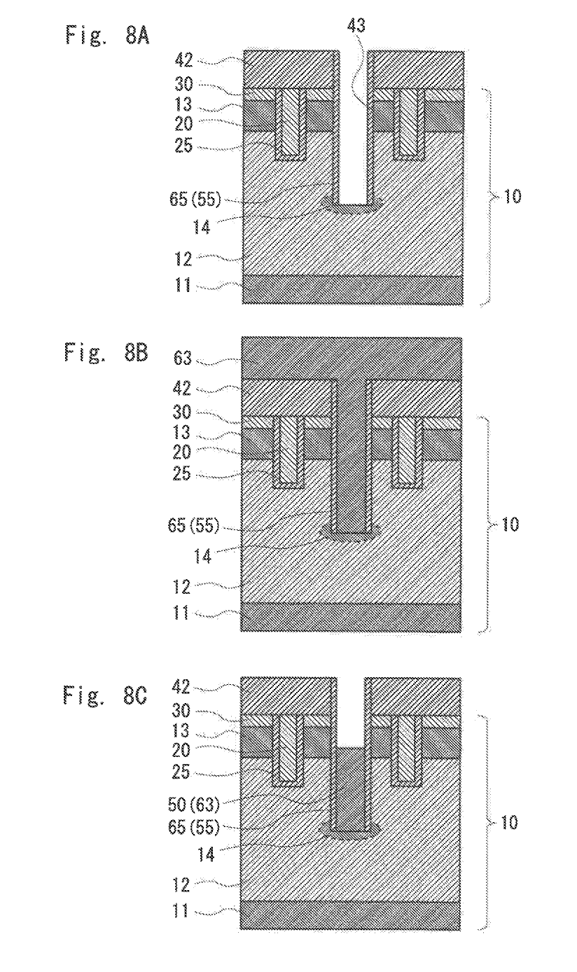

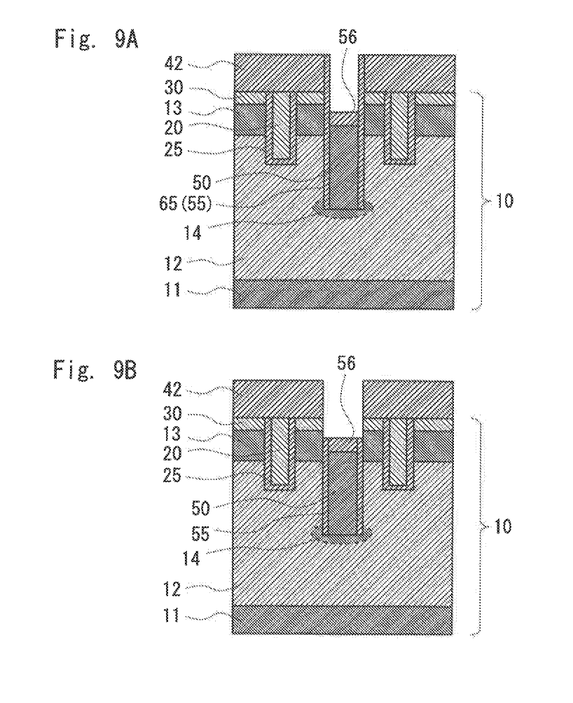

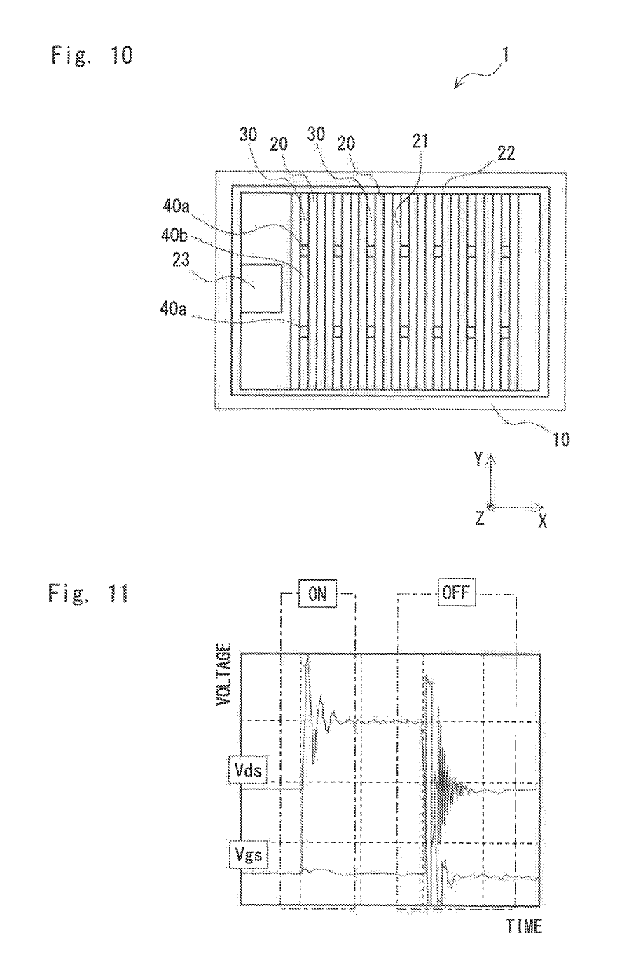

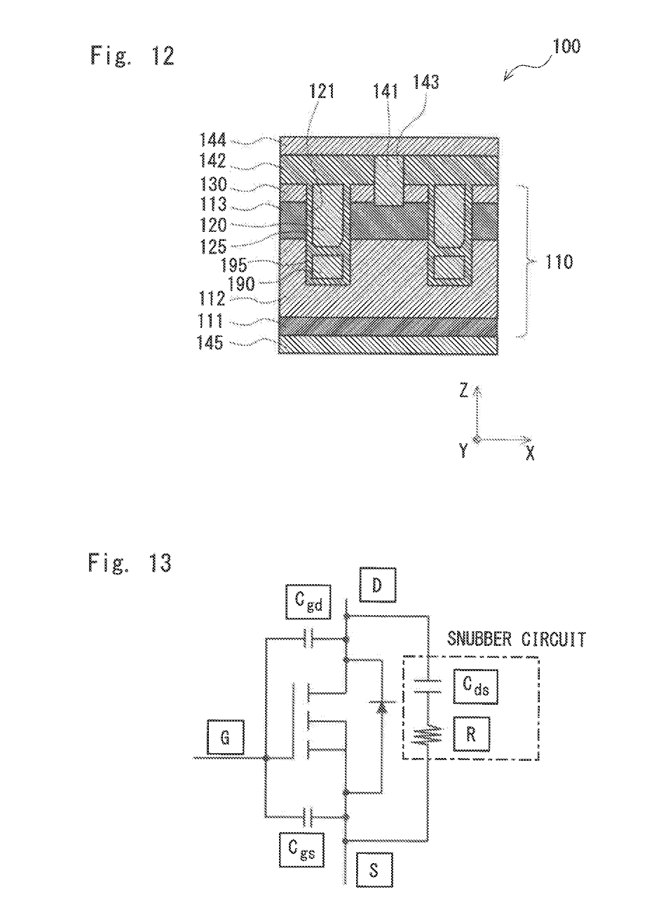

Next, a method of manufacturing the semiconductor device 1 according to the embodiment will be described. FIGS. 4A to 9B are cross-sectional views illustrating the method of manufacturing the semiconductor device according to the embodiment. FIG. 4A illustrates a process for forming a mask in order to form the gate trenches. FIG. 4B illustrates a process for mask lithography. FIG. 4C illustrates a process for mask patterning. FIG. 5A illustrates an ion etching process in order to form the gate trenches. FIG. 5B illustrates a process of edge-rounding oxidation of the gate trenches. FIG. 5C illustrates a deposition process of polysilicon in order to form the gate electrodes. FIG. 6A illustrates a process for plasma-etching the polysilicon in order to form the gate electrodes. FIG. 6B illustrates a process for impurity implantation in order to form the base layer. FIG. 6C illustrates a process for impurity implantation in order to form the source layer. FIG. 7A illustrates a process for forming the interlayer insulating film. FIG. 7B illustrates a process for plasma etching in order to form the contact hole and a process for impurity implantation in order to form the connection layer. FIG. 7C illustrates a process for field plate oxidation. FIG. 8A illustrates a process for ion-etching an oxide film on the bottom surface of the contact hole. FIG. 8B illustrates a deposition process of polysilicon in order to form the snubber conductive layer. FIG. 8C illustrates a process for etching back polysilicon in order to form the snubber conductive layer. FIG. 9A illustrates a process for forming the oxide film in order to form the buried insulating film. FIG. 9B illustrates a process for etching the oxide film in order to form the contact.

As shown in FIG. 4A, firstly the semiconductor substrate 10 is prepared. The semiconductor substrate 10 includes the drain layer 11 and the drift layer 12. The drain layer 11 is, for example, an n⁺ type bulk silicon substrate doped with a high concentration of an n-type impurity. The drift layer 12 is a silicon layer epitaxially grown on a silicon substrate. Thus, the semiconductor substrate 10 is composed of the silicon substrate with the drift layer 12 formed thereon.

Next, a mask 60 is formed on the semiconductor substrate 10. For example, the mask 60 is formed on the epitaxially-grown drift layer 12. The mask 60 is used as a mask to form the gate trenches. The mask 60 is, for example, a silicon oxide film or the like.

Next, as shown in FIG. 4B, a resist 61 is formed on the mask 60. Then, the resist 61 is patterned by, for example, normal lithography. In the resist 61, a pattern including opened regions which will become the gate trenches 21 is formed.

Next, as shown in FIG. 4C, the mask 60 is etched using the resist 61 having the pattern formed thereon as a mask. As a result, a pattern is formed in the mask 60, in which the pattern includes opened regions which will become the gate trenches.

Next, as shown in FIG. 5A, the resist 61 is removed, for example, by ashing. Next, the semiconductor substrate 10 is etched using the patterned mask 60 as a mask. In this way, the gate trenches 21 extended in one direction are formed in the upper surface of the semiconductor substrate 10. For example, the plurality of gate trenches 21 are formed. The gate trenches 21 are formed to be parallel to each other.

Next, as shown in FIG. 5B, the gate insulating films 25 are formed on the inner surfaces of the gate trenches 21 formed in the upper surface of the semiconductor substrate 10 using the mask 60 as a mask. For example, the gate insulating films 25 are formed by performing edge-rounding oxidation on the inner surfaces of the gate trenches 21. In this manner, the gate insulating films 25 are formed on the inner surfaces of the gate trenches 21, that is, the gate insulating films 25 are formed on the side and bottom surfaces of the gate trenches 21.

Next, as shown in FIG. 5C, for example, a P-type polysilicon film 62 is formed on the mask 60 and inside the gate trenches 21. The polysilicon film 62 is formed, for example, by the CVD (Chemical Vapor Deposition) method.

Next, as shown in FIG. 6A, a part of the polysilicon film disposed above the upper surface of the semiconductor substrate 10 is removed. In order to remove the polysilicon film 62, the polysilicon film 62 is etched back by, for example, the plasma etching method. Then, the polysilicon films 62 are buried in the gate trenches 21. The polysilicon films 62 buried in the gate trenches 21 become the gate electrodes 20. In this way, the gate electrodes 20 are formed inside the gate trenches 21.

Next, as shown in FIG. 6B, a P-type impurity such as boron (B) or the like is introduced into the upper part of the drift layer 12 by the ion implantation method. In this manner, the P-type base layer 13 is formed in the upper part of the semiconductor substrate 10. The lower end of the base layer 13 is formed above the lower ends of the gate electrodes 20.

Next, as shown in FIG. 6C, a high concentration of an N-type impurity such as arsenic (As) or the like is introduced into the upper part of the base layer 13 by the ion implantation method. In this way, the N⁺ type source layer 30 is formed on the base layer 13.

Next, as shown in FIG. 7A, the interlayer insulating film 42 is formed on the source layer 30 by, for example, the CVD or the like. The interlayer insulating film 42 includes, for example, a silicon oxide film.

Next, as shown in FIG. 7B, the contact hole 43 is formed. The contact hole 43 is formed so as to be extended in the same direction as the direction in which the gate electrodes 20 are extended. Further, the contact hole 43 is formed so as to penetrate the interlayer insulating film 42, the source layer 30, and the base layer 13 and to reach the drift layer 12. The contact hole 43 is formed between the two gate trenches 21. The contact hole 43 is formed by performing etching back by the plasma etching method, for example, using the patterned interlayer insulating film 42 as a mask. Then, a P-type impurity is ion-implanted into the drift layer 12 using the interlayer insulating film 42 as a mask. In this way, the connection layer 14 of the second conductivity type including the bottom surface of the contact hole 43 is formed near the bottom surface of the contact hole 43.

Next, as shown in FIG. 7C, the inner surface of the contact hole 43 is oxidized using the interlayer insulating film 42 as a mask. Then, an insulating film 65 which becomes the snubber sidewall insulating film 55 is formed on the inner surface of the contact hole 43, i.e., the side and bottom surfaces of the contact hole 43. The insulating film 65 is, for example, a silicon oxide film.

Next, as shown in FIG. 8A, a part of the insulating film 65 disposed at the bottom surface of the contact hole 43 is removed by, for example, anisotropic etching using the ion etching method. The rest of the insulating film 65 including the snubber sidewall insulating film 55 remains on the side surface of the contact hole 43.

Next, as shown in FIG. 8B, for example, a P-type polysilicon film 63 is formed on the interlayer insulating film 42 and inside the contact hole 43. The polysilicon film 63 is formed, for example, by the CVD method.

Next, as shown in FIG. 8C, the polysilicon film 63 on the interlayer insulating film 42 and the polysilicon film 63 disposed in the upper part of the contact hole 43 are removed by the etch back method. Then, the polysilicon film 63 is buried at the lower part of the contact hole 43. The polysilicon film 63 buried at the lower part of the contact hole 43 is referred to as the snubber conductive layer 50. In this way, the snubber conductive layer 50 is formed at the lower part of the contact hole 43 from which the snubber sidewall insulating film 55 disposed at the bottom surface of the contact hole 43 is removed. At this time, the snubber conductive layer 50 is formed so as to be in contact with the connection layer 14. Further, when viewed from above, the length of the connection layer 14 in the X axis direction is made greater than the length of the snubber conductive layer in the X axis direction by the oxidation heat treatment or the like.

At this time, the upper end of the snubber conductive layer 50 is positioned above the lower end of the base layer 13. Further, the lower end of the snubber conductive layer 50 is positioned below the lower end of the base layer 13. Note that the upper end of the snubber conductive layer 50 may be positioned lower than the upper end of the base layer 13.

Next, as shown in FIG. 9A, the buried insulating film 56 is formed on the snubber conductive layer 50 formed inside the contact hole 43, for example, by the CVD method.

Next, as shown in FIG. 9B, a part of the insulating film 65 formed on the side surface of the contact hole 43 that is disposed above the upper surface of the buried insulating film 56 is removed by, for example, wet etching. Then, the snubber sidewall insulating film 55 remains on the side surface of the snubber conductive layer 50. The insulating film 65 on the side surface of the buried insulating film 56 may be integrated with the buried insulating film 56.

Next, the contact 41 which is to be connected to the source layer 30 is formed above the snubber conductive layer 50 in the contact hole 43. For example, a material of the contact 41 contains tungsten (W). After that, the source electrode 44 is formed on the interlayer insulating film 42 so as to be connected to the contact 41. A material of the source electrode 44 contains aluminum (Al). Note that the contact 41 and the source electrode 44 may be integrally formed. For example, a process of the source electrode 44 formed on the interlayer insulating film 42 and a process of the contact hole 43 filled by the contact 41 may be performed at the same time.

When the source electrode 44 is formed, the snubber conductive layer 50 is connected to the source electrode 44 at the circumferential part of the cell. Thus, the snubber conductive layer 50 can be used as a source potential.

The drain electrode 45 is formed so as to cover the drain layer 11 from the lower surface of the semiconductor substrate 10, that is, from under the drain layer 11. Thus, the drain electrode 45 is connected to the drain layer 11. A material of the drain electrode 45 contains, for example, aluminum (Al).

In the manner described above, as shown in FIG. 3, in the semiconductor device 1, the buried insulating film 56 is formed on the snubber conductive layer 50, and the snubber conductive layer noncontacting region 40b where the contact 41 is formed on the buried insulating film 56 is formed. The snubber conductive layer noncontacting regions 40b are formed so as to be extended in the Y axis direction.

On the other hand, the buried insulating layer 56 is removed by, for example, wet etching. Then, the upper surface of the snubber conductive layer 50 is exposed in the contact hole 43. Next, the contact 41 which is to be connected to the source layer 30 is formed above the snubber conductive layer 50 in the contact hole 43. The contact 41 is formed so as to be electrically connected to the snubber conductive layer 50. For example, the contact 41 is brought into contact with the snubber conductive layer 50. After that, the source electrode 44 is formed on the interlayer insulating film 42 so as to be connected to the contact 41. Note that as described above, the contact 41 and the source electrode 44 may be integrally formed. The method of forming the drain electrode 45 is as described above.

In the manner described above, as shown in FIG. 2, the snubber conductive layer contacting regions 40a each including the contact 41 formed therein so as to be connected to the snubber conductive layer 50 are formed in the semiconductor device 1. The snubber conductive layer contacting region 40a is formed at the end parts or both ends of the snubber conductive layer noncontacting region 40b that is extended in the Y axis direction.

Next, effects of the present embodiment will be described.

FIG. 10 is a top view illustrating the semiconductor device 1 according to the embodiment. As shown in FIG. 10, in the semiconductor device 1, in the snubber conductive layer contacting region 40a, the snubber conductive layer 50 and the contact 41 are electrically connected. In the snubber conductive layer noncontacting region 40b, the snubber conductive layer 50 and the contact 41 are not electrically connected. Therefore, the snubber conductive layer 50 between the snubber conductive layer contacting regions 40a is a resistance of the snubber circuit. The resistance value of the snubber circuit can be controlled as necessary by removing the buried insulating film 56 in the snubber conductive layer noncontacting region 40b. In FIG. 10, as compared with FIG. 1, the number of the snubber conductive layer contacting regions 40a is reduced to thereby reduce regions which become the resistance of the snubber circuit. In this way, the resistance of the snubber circuit can be optimized by optimizing the number of the snubber conductive layer contacting regions 40a.

On the other hand, the snubber conductive layer 50 is formed at the lower part of the contact 41, and the snubber conductive layer 50 is connected to the source electrode 44 at the circumferential part. Further, the snubber sidewall insulating film 55 is formed on the side surface of the snubber conductive layer 50. It is thus possible to prevent to expand a depletion layer between the drift layer 12 and the snubber conductive layer 50. In this manner, it is possible to reduce a decrease of the capacitance between the source layer 30 and the drain layer 11 to optimize the capacitance of the snubber circuit.

Accordingly, in the semiconductor device 1, the resistance value of the snubber conductive layer 50 functioning as the resistance of the snubber circuit can be controlled. Moreover, it is possible to reduce the decrease in the capacitance between the source and the drain functioning as the capacitance of the snubber circuit. It is therefore possible to reduce noise caused by EMI by optimizing the resistance and capacitance of the snubber circuit.

The lower surface of the snubber conductive layer 50 is not covered with the insulating film. The snubber conductive layer 50 is connected to the connection layer 14. Therefore, as compared with the case where the snubber conductive layer 50 is covered with the insulating film, the depletion layer can be more rapidly expanded when a voltage is applied, and thus the switching speed can be improved.

When viewed from above, the length of the connection layer 14 in the X axis direction is greater than the length of the snubber conductive layer 50 in the X axis direction. With such a configuration, it is possible to prevent the electric fields from being concentrated near the gate electrodes 20. Further, by disposing the layers in such a way that the upper end of the snubber conductive layer 50 is positioned above the lower end of the base layer 13, and the lower end of the snubber conductive layer 50 is positioned below the lower end of the base layer, it is possible to prevent the electric fields from being concentrated near the gate electrodes 20.

Since the resistance value of the snubber circuit can be specified by the length of the snubber conductive layer 50 in the Y axis direction, it is not necessary to increase the length of the snubber conductive layer 50 in the Z axis direction. Consequently, the thickness and the size of the semiconductor device 1 can be reduced.

Although the invention made by the present inventor has been described in detail based on the embodiment, it is obvious that the present disclosure is not limited to the above-described embodiments, and various modifications can be made without departing from the scope thereof.

While the invention has been described in terms of several embodiments, those skilled in the art will recognize that the invention can be practiced with various modifications within the spirit and scope of the appended claims and the invention is not limited to the examples described above.

Further, the scope of the claims is not limited by the embodiments described above.

Furthermore, it is noted that, Applicant's intent is to encompass equivalents of all claim elements, even if amended later during prosecution.

What is claimed is:

1. A semiconductor device comprising:
a drift layer of a first conductivity type;
a base layer of a second conductivity type disposed on the drift layer;
a source layer of the first conductivity type disposed on the base layer and having a resistance lower than that of the drift layer;
a gate trench extended in one direction in an upper surface of the source layer, penetrating the source layer and the base layer, and reaching the drift layer;
a gate electrode disposed inside the gate trench;
a gate insulating film disposed between the gate electrode and the source layer, between the gate electrode and the base layer, and between the gate electrode and the drift layer;
an interlayer insulating film disposed on the source layer;
a contact hole extended in the one direction in an upper surface of the interlayer insulating film, penetrating the interlayer insulating film, the source layer, and the base layer, and reaching the drift layer;
a snubber conductive layer disposed in a lower part of the contact hole and extended in the one direction;
a snubber sidewall insulating film disposed between a side surface of the snubber conductive layer and the drift layer; and
a contact disposed above the snubber conductive layer in the contact hole and connected to the source layer.

2. The semiconductor device according to claim 1, further comprising:
a snubber conductive layer contacting region where the contact is electrically connected to the snubber conductive layer; and
a snubber conductive layer noncontacting region where an insulating film is disposed between the contact and the snubber conductive layer.

3. The semiconductor device according to claim 2, wherein the snubber conductive layer contacting regions are disposed at both ends of the snubber conductive layer noncontacting region extended in the one direction.

4. The semiconductor device according to claim 1, further comprising a connection layer of the second conductivity type including a bottom surface of the contact hole, disposed near the bottom surface of the contact hole, and being in contact with the snubber conductive layer.

5. The semiconductor device according to claim 4, wherein, when viewed from above, a length of the connection layer in a direction orthogonal to the one direction is greater than a length of the snubber conductive layer in the direction.

6. The semiconductor device according to claim 1, wherein
an upper end of the snubber conductive layer is positioned above a lower end of the base layer, and
a lower end of the snubber conductive layer is positioned below the lower end of the base layer.

7. The semiconductor device according to claim 1, further comprising:
a source electrode disposed on the interlayer insulating film and connected to the contact;
a drain layer in contact with a lower surface of the drift layer; and
a drain electrode connected to the drain layer, wherein the snubber conductive layer is connected to the source electrode.

8. The semiconductor device according to claim 1, wherein
a plurality of the gate trenches are disposed, and
the contact hole is disposed between two of the gate trenches.

9. A method of manufacturing a semiconductor device comprising:
forming a gate trench extended in one direction in an upper surface of a semiconductor substrate, a drift layer of a first conductivity type being formed on the semiconductor substrate;
forming a gate insulating film on an inner surface of the gate trench;
forming a gate electrode inside the gate trench;
forming a base layer of a second conductivity type in an upper part of the semiconductor substrate;
forming a source layer of the first conductivity type on the base layer;
forming an interlayer insulating film on the source layer;
forming a contact hole so as to be extended in one direction in an upper layer of the interlayer insulating film, penetrating the interlayer insulating film, the source layer, and the base layer, and reaching the drift layer;
forming a snubber sidewall insulating film on an inner surface of the contact hole;
removing the snubber sidewall insulating film disposed at a bottom surface of the contact hole;
forming a snubber conductive layer in a lower part of the contact hole from which the snubber sidewall insulating film disposed at a bottom surface of the contact hole is removed; and
forming a contact above the snubber conductive layer in the contact hole so as to be connected to the source layer.

10. The method according to claim 9, wherein in the forming of the contact,
the contact is formed so that there is a snubber conductive layer contacting region where the contact is electrically connected to the snubber conductive layer, and
the contact is formed so that there is a snubber conductive layer noncontacting region where the contact is formed on the insulating film.

11. The method according to claim 10, wherein the snubber conductive layer contacting region is formed at both ends of the snubber conductive layer noncontacting region extended in the one direction.

12. The method according to claim 9, further comprising, after the forming of the contact hole, forming a connection layer of the second conductivity type near a bottom surface of the contact hole, the connection layer including the bottom surface of the contact hole, wherein, in the forming of the snubber conductive layer, the snubber conductive layer is formed so as to be in contact with the connection layer.

13. The method according to claim 12, wherein, when viewed from above, a length of the connection layer in a direction orthogonal to the one direction is made greater than a length of the snubber conductive layer in the direction.

14. The method according to claim 9, wherein
an upper end of the snubber conductive layer is positioned above a lower end of the base layer, and
a lower end of the snubber conductive layer is positioned below a lower end of the base layer.

15. The method according to claim 9, further comprising:
forming a source electrode on the interlayer insulating film so that it is in contact with the contact; and
forming a drain electrode on a lower surface of the semiconductor substrate, wherein in the forming of the source electrode, the snubber conductive layer is connected to the source electrode.

16. The method according to claim 9, wherein
a plurality of the gate trenches are formed, and
the contact hole is formed between two of the gate trenches.
